(19) United States
(12) Patent Application Publication
(10) Pub. No.: US 2007/0023815 A1
(43) Pub. Date: Feb. 1, 2007

(54) Non-volatile memory device and associated method of manufacture

(76) Inventors: Dong-Yean Oh, Seoul (KR); Jeong-Hyuk Choi, Seongnam-si (KR); Jai-Hyuk Song, Seoul (KR); Jong-Kwang Lim, Suwon-si (KR); Jae-Young Ahn, Seongnam-si (KR); Ki-Hyun Hwang, Seongnam-si (KR); Jin-Gyun Kim, Yongin-si (KR); Hong-Suk Kim, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/493,605

(22) Filed: Jul. 27, 2006

(30) Foreign Application Priority Data
Jul. 27, 2005 (KR) 2005-68567
Nov. 25, 2005 (KR) 2005-113639

(51) Int. Cl. H01L 29/76

(52) U.S. Cl. 257/314

(57) ABSTRACT

A non-volatile memory device comprises a floating gate formed across an active region of a semiconductor substrate, and a control gate electrode formed over the floating gate. An insulation pattern is formed between the floating gate and the active region such that the insulation pattern makes contact with a bottom edge and a sidewall of the floating gate.

### BACKGROUND OF THE INVENTION

1. Field of the Invention

Embodiments of the invention relate generally to semiconductor devices and associated methods of manufacture. More particularly, embodiments of the invention relate to non-volatile semiconductor memory devices and associated methods of manufacture.

A claim of priority is made to Korean Patent Application No. 2005-68567 filed Jul. 27, 2005 and Korean Patent Application No. 2005-113639 filed Nov. 25, 2005. The respective disclosures of these applications are hereby incorporated by reference in their entirety.

2. Description of Related Art

Non-volatile memory devices are capable of storing data even when disconnected from an external power source. One way to achieve this capability is by adding a floating gate structure to a metal-oxide semiconductor (MOS) transistor and storing charges in the floating gate structure using Fowler-Nordheim tunneling or hot electron injection. In order to effectively store charges using these techniques, the floating gate structure is generally surrounded by a tunnel insulation layer so that charges to be stored in the floating gate structure must move through the tunnel insulation layer.

For example, FIG. 1 is a plan view illustrating a conventional non-volatile memory device including a floating gate structure and FIGS. 2 and 3 are cross-sectional views of the conventional non-volatile memory device taken along respective lines I-I′ and II-II′ in FIG. 1.

Referring to FIGS. 1 through 3, the conventional non-volatile memory device comprises a device isolation layer 20 formed on a semiconductor substrate 10 to define an active region. A plurality of word lines WL are formed across the active region and device isolation layer 20. A plurality of floating gates 32 are formed over the active region between semiconductor substrate 10 and respective word lines WL, and a control gate electrode 36 is formed over each of floating gates 32. Each control gate 36 is separated from a corresponding one of floating gates 32 by an intergate dielectric 34 and each one of floating gates 32 is separated from the active region by a corresponding tunnel insulation layer 30.

Each of floating gates 32 is typically formed to be equal in width or wider than a corresponding underlying portion of the active region. Accordingly, each of floating gates 32 partially overlaps with a portion of device isolation layer 20. Device isolation layer 20 has a portion that protrudes above a top surface of the active region. The protruding portion of device isolation layer 20 generally makes contact with at least a portion of each sidewall of floating gates 32.

An interface trap density can be used as an index to indicate the reliability of a transistor. Interface trap density is a metric representing an amount of silicon lattice damage at an interface between tunnel insulating layer 30 and semiconductor substrate 10 due to Fowler-Nordheim (FN) tunneling in the non-volatile memory device. The interface trap density tends to increase with an increased number of program and erase operations performed in the device. As the interface trap density increases, charges become trapped at the interface, resulting in a gradual decrease in a gap between a program threshold voltage and an erase threshold voltage. Due to the decrease in the gap between the program and erase threshold voltages, a readout margin of the device tends to decrease accordingly.

In the non-volatile memory device, the active region is often defined using a shallow trench isolation (STI) process. Unfortunately, physical stress from the STI process can cause lattice damage in edges of the active region. As a result, an edge thinning phenomenon can occur in tunnel insulation layer 30, which is formed in a subsequent process. For instance, FIG. 4 illustrates edge-thinning in a region of FIG. 3 labeled “E_{g}”.

Referring to FIG. 4, edge-thinning occurs where an edge portion of tunnel insulation layer 30 has a thickness tₑ and a center portion of tunnel insulation layer 30 over the active region has a thickness tₒₓ, and thickness tₑ is less than tₒₓ. The edge-thinning causes an intense electric field to be concentrated at edges of the active region during program and erase operations. Accordingly, the trap density of each of floating gates 32 tends to increase abruptly toward the edges of the active region.

Further, as the active region becomes narrower, the relative proportion of tunnel insulation layer 30 having thinned edges tends to increase. Accordingly, as the integration density of non-volatile semiconductor devices having a tunnel insulation layer affected by edge-thinning increases, the reliability of the devices tends to decrease.

### SUMMARY OF THE INVENTION

According to one embodiment of the invention, a non-volatile memory device comprises a device isolation layer defining an active region on a semiconductor substrate, a tunnel insulation layer disposed on the active region, an insulation pattern disposed on edges of the active region, and a floating gate disposed on the tunnel insulation layer and the insulation pattern. A control gate electrode is disposed on the floating gate across the active region and the device isolation layer, and an intergate dielectric is interposed between the floating gate and the control gate electrode. The insulation pattern is in contact with a bottom edge and a sidewall of the floating gate.

According to another embodiment of the invention, a non-volatile memory device comprises a device isolation layer disposed on a semiconductor substrate to define an active region. Insulation patterns are disposed on opposite edges of the active region, a tunnel insulation layer is disposed on the active region between the insulation patterns, and a floating gate is disposed on the tunnel insulation layer and the insulation patterns, wherein the floating gate is narrower than the active region. In addition, a control gate electrode is disposed on the floating gate across the active region and the device isolation layer, and an intergate dielectric interposed between the floating gate and the control gate electrode. The insulation pattern is in contact with a bottom edge and a sidewall of the floating gate.

According to still another embodiment of the invention, a non-volatile memory device comprises a device isolation layer disposed on a semiconductor substrate to define an active region, a tunnel insulation layer disposed on the active region, insulation patterns disposed on the tunnel insulation layer at opposite edges of the active region, and a floating gate disposed on the tunnel insulation layer and the insulation pattern, wherein the floating gate is wider than the active region. In addition, a control gate electrode is disposed on the floating gate across the active region and the device isolation layer, and an intergate dielectric interposed between the floating gate and the control gate electrode. The insulation pattern is in contact with a bottom edge and a sidewall of the floating gate.

According to still another embodiment of the invention, a method of manufacturing a non-volatile memory device comprises etching a semiconductor substrate to form a trench defining an active region, forming a device isolation layer in the trench, the device isolation layer having protruding portions extending above a top surface of the active region, forming insulation patterns to conformally cover sidewalls of the protruding portions of the device isolation layer and edges of the active region, forming a tunnel oxide layer on the active region, and forming a floating gate pattern on the tunnel oxide layer and the insulation patterns.

According to yet another embodiment of the invention, a method of manufacturing a non-volatile memory device comprises forming a device isolation layer having protruding portions extending upward from a semiconductor substrate and defining an active region in the semiconductor substrate, forming a first insulation layer to conformally covering the protruding portions of the device isolation layer and the active region, forming a spacer pattern comprising silicon germanium on sidewall portions of the first insulation layer formed on the protruding portions of the device isolation layer, the spacer pattern covering edges of the active region, etching the first insulating layer using the spacer pattern as an etch mask to form an edge insulation pattern covering the edges of the active region, removing the spacer pattern, and forming a tunnel insulation layer on the active region.

According to yet another embodiment of the invention, a method of manufacturing a non-volatile memory device comprises forming a device isolation layer having a protruding portions extending upward from a semiconductor substrate and defining an active region in the semiconductor substrate, etching back sidewalls of the protruding portions to increase a distance between adjacent protruding portions on opposite sides of the active region to more than a width of the active region, forming a first insulation layer conformally covering the protruding portions and the active region, forming a spacer pattern comprising silicon germanium on sidewall portions of the first insulation layer formed on the protruding portions of the device isolation layer, the spacer pattern covering edges of the active region, etching the first insulation layer using the spacer pattern as an etch mask to form an edge insulation pattern covering the edges of the active region, removing the spacer pattern, and forming a tunnel insulation layer on the active region.

### BRIEF DESCRIPTION OF THE DRAWINGS

The invention is described below in relation to several embodiments illustrated in the accompanying drawings. Throughout the drawings like reference numbers indicate like exemplary elements, components, or steps. In the drawings:

FIGS. 1 through 4 are plan and cross-sectional views illustrating a conventional non-volatile memory device;

FIGS. 5 through 7 are cross-sectional views of various non-volatile memory devices according to selected embodiments of the invention;

FIGS. 8 through 18 are cross-sectional views illustrating a method of manufacturing a non-volatile memory device according to an embodiment of the invention;

FIGS. 19 through 21 are cross-sectional views illustrating a method of manufacturing a non-volatile memory device according to another embodiment of the invention;

FIGS. 22 through 26 are cross-sectional views illustrating a non-volatile memory device and a method of manufacturing a non-volatile memory device according to still another embodiment of the invention;

FIGS. 27 through 32 are cross-sectional views illustrating a non-volatile memory device and a method of manufacturing a non-volatile memory device according to still another embodiment of the invention;

FIGS. 33 through 38 are cross-sectional views illustrating various modifications that can be made to selected embodiments of the invention; and,

FIGS. 39 through 45 are cross-sectional views illustrating a method of manufacturing a non-volatile memory device according to still another embodiment of the invention.

### DESCRIPTION OF EXEMPLARY EMBODIMENTS

Exemplary embodiments of the invention are described below with reference to the corresponding drawings. These embodiments are presented as teaching examples. The actual scope of the invention is defined by the claims that follow.

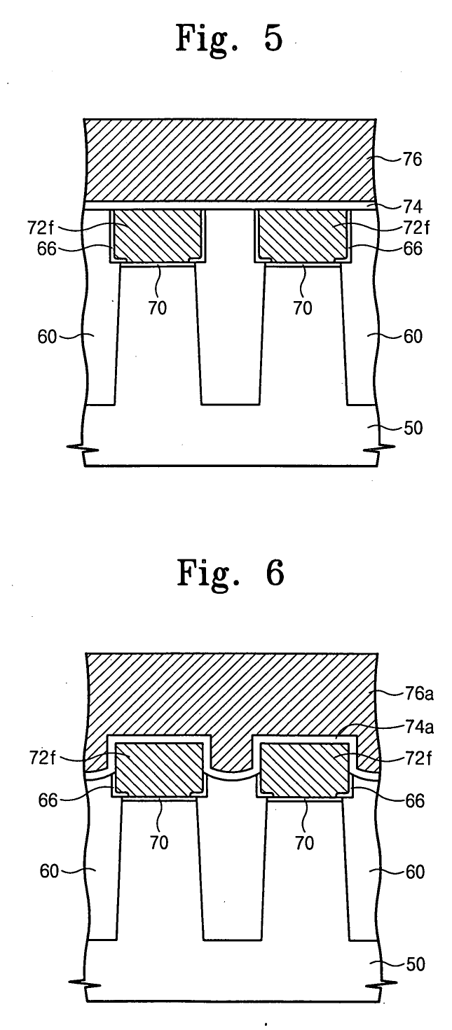

FIG. 5 is a cross-sectional view of a non-volatile memory device according to an embodiment of the invention.

Referring to FIG. 5, a device isolation layer 60 is formed in a semiconductor substrate 50 to define an active region, and a tunnel insulation layer 70 is formed on the active region. Device isolation layer 60 has a portion that protrudes above the active region. An insulation pattern 66 is formed on tunnel insulation layer 70 at edges of the active region and on sidewalls of the protruding portion of device isolation layer 60. A floating gate 72f is formed on tunnel insulation layer 70 and insulation pattern 66 and a control gate electrode 76 is formed on floating gate electrode 72f across the active region and device isolation layer 60. An intergate dielectric 74 is interposed between floating gate 72f and control gate electrode 76.

Insulation pattern 66 is formed in continuous contact with a bottom edge and a sidewall of floating gate 72f. A top surface of floating gate 72f is aligned with a top surface of device isolation layer 60. Accordingly, insulation pattern 66 is interposed between device isolation layer 60 and an entire surface of the sidewall of floating gate 72f. Floating gate 72f is typically wider than the active region, and therefore the edge of floating gate 72f partially overlaps with device isolation layer 60.

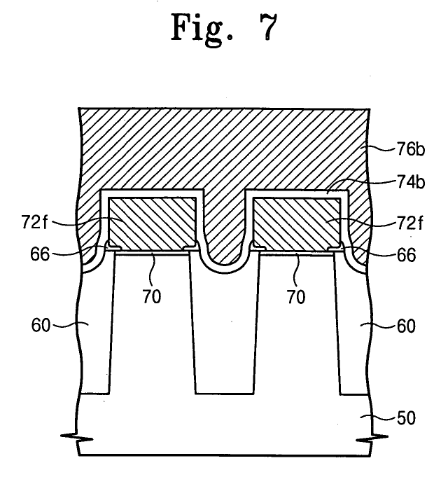

Referring to FIG. 6, the protruding portion of device isolation layer 60 is recessed to be lower than the top surface of floating gate 72f. In FIG. 6, sidewalls of floating gate 72f are partially exposed between device isolation layer 60 and an intergate dielectric 74a is formed on a portion of the sidewall of floating gate 72f in addition to the top surface of floating gate 72f. A portion of a control gate electrode 76a extends below the top surface of floating gate 72f to increase an area of control gate electrode 76a opposite floating gate 72f. Insulation pattern 66 is in contact with parts of bottom edges and sidewalls of floating gate 72f.

Referring to FIG. 7, device isolation layer 60 is further recessed so that at least a portion of its top surface is lower than a top surface of the active region. A control gate electrode 76b extends below the sidewalls of floating gate 72f to be lower than the top surface of the active region. A downward sloping portion of control gate electrode 76b laterally decentralizes a vertical electric field between the edge of the active region and floating gate 72f, thereby weakening the vertical electric field. In the device illustrated in FIG. 7, insulation pattern 66 is also structured to contact parts of bottom edges and sidewalls of floating gate 72f. As a result, an electric field is prevented from concentrating at corners of floating gate 72f.

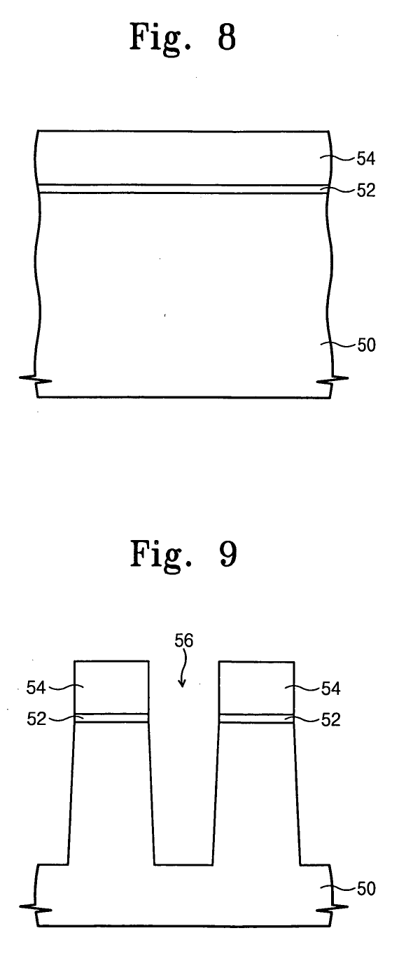

FIGS. 8 through 18 are cross-sectional views illustrating a method of manufacturing a non-volatile memory device according to an embodiment of the invention.

Referring to FIG. 8, a buffer oxide layer 52 and a hard mask layer 54 are formed on a semiconductor substrate 50. Hard mask layer 54 typically comprises a silicon nitride layer, a silicon oxide layer, and an anti-reflective film, stacked in the order named. One purpose of buffer oxide layer 52 is to prevent stress from the silicon nitride layer from being applied to the substrate.

Referring to FIG. 9, hard mask layer 54, buffer oxide layer 52, and semiconductor substrate 50 are etched to form a trench 56 defining active regions. A sacrificial oxidation process can also be performed during or after the formation of trench 56 to repair crystal defects in semiconductor substrate 50.

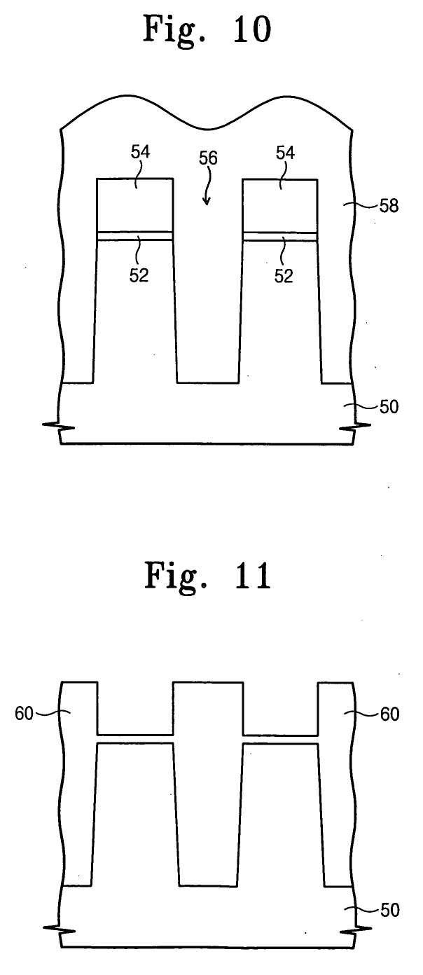

Referring to FIG. 10, a buried insulation layer 58 is formed over semiconductor substrate 50 to fill trench 56. Buried insulation layer 58 comprises an insulating material having gap-filling properties designed to prevent voids from forming in trench 56.

Referring to FIG. 11, buried insulation layer 58 is planarized down to a top surface of hard mask layer 54 to form a device isolation layer 60 in trench 56. Buried insulation layer 58 is preferably planarized using a chemical mechanical polishing (CMP) process. Hard mask layer 54 is then removed to expose sidewalls of device isolation layer 60 protruding above top surfaces of the active regions.

The active regions illustrated in FIG. 11 typically have upper corners with small radii of curvature. These small radii of curvature tend to cause electric fields to be concentrated at edges of the active regions. The strength of these electric fields can be lessened by increasing the radii of curvature of the corners.

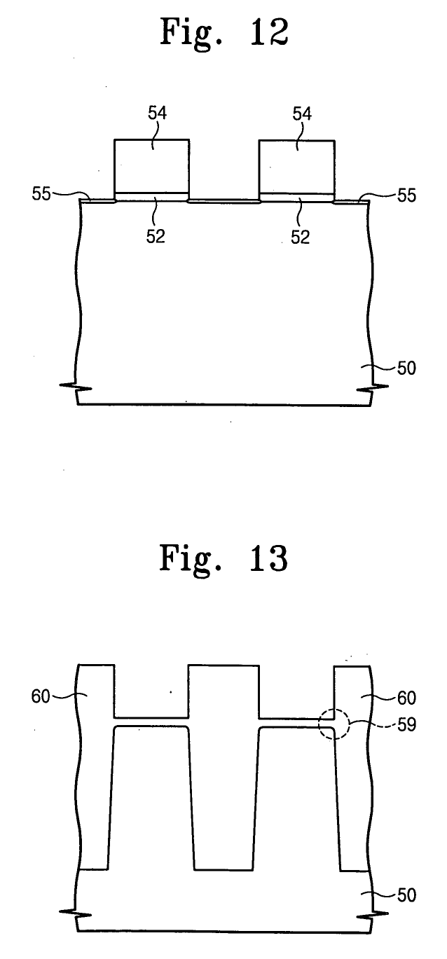

FIGS. 12 and 13 are cross-sectional views illustrating a method of increasing the radius of curvature of corners formed at edges of the active region when trench 56 is formed.

Referring to FIG. 12, when hard mask pattern 54 and buffer oxide layer 52 are patterned to form a mask pattern before the formation of trench 56, a portion of semiconductor substrate 50 is exposed. Semiconductor substrate 50 is annealed to form a sacrificial thermal oxide layer 55 on the exposed region. Sacrificial thermal oxide layer 55 extends under the mask pattern to form a bird's beak.

Referring to FIG. 13, sacrificial thermal oxide layer 55 is removed. Semiconductor substrate 50 is then etched using the mask pattern as an etch mask to form trench 56. Then, buried insulation layer 58 is formed and planarized. Next, hard mask layer 54 is removed to form device isolation layer 60 having a structure similar to that illustrated in FIG. 11. However, corners of the active regions such as a corner 59 have larger a radii of curvature than the corners of the active region illustrated in FIG. 11.

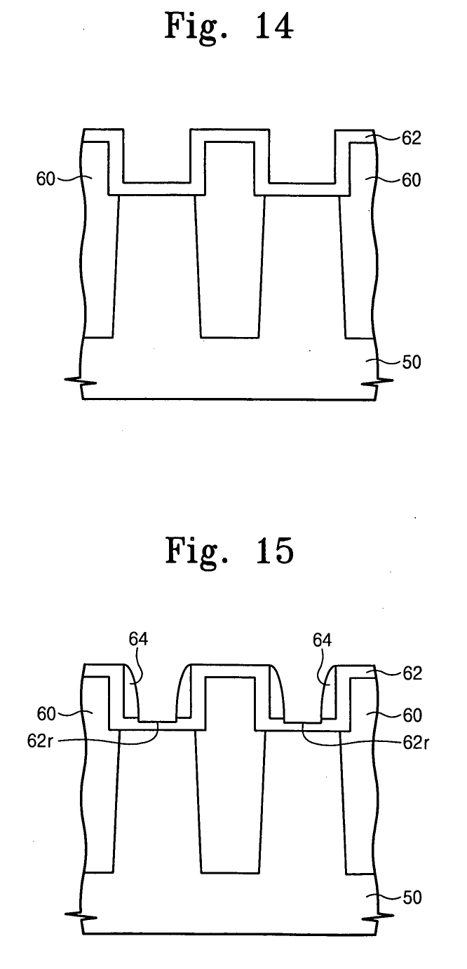

Referring to FIG. 14, after device isolation layer 60 is formed using the method illustrated in FIG. 11 or 13, buffer oxide layer 52 is removed to expose the active regions. Buffer oxide layer 52 is preferably removed by an isotropic etching process. Preferably, a portion of device isolation layer 60 is etched simultaneously with buffer oxide layer 52. Due to the isotropic etching process, the space between the protrusions of device isolation layer 60 typically become greater than the width of the active region.

Next, an insulation layer 62 is conformally formed over the entire surface of semiconductor substrate 50. Insulation layer 62 is preferably formed of an oxide layer deposited by a CVD process.

Referring to FIG. 15, a material having an etch selectivity relative to insulation layer 62 is conformally formed on insulation layer 62 and anisotropically etched to form a spacer pattern 64. Even though spacer pattern 64 is formed of a material having the etch selectivity relative to insulation layer 62, insulation layer 62 may be partially etched when spacer pattern 64 is formed. For example, where insulation layer 62 is etched, a recessed region 62r shown in FIG. 15 may be formed on the active region between spacer patterns 64. Accordingly, insulation layer 62 may be thicker at edge portions of the active regions than at center portions of the active regions.

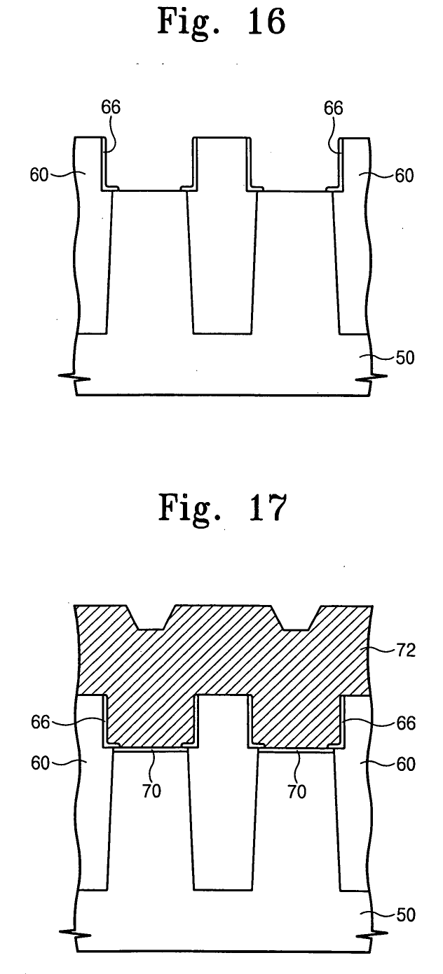

Referring to FIG. 16, spacer patterns 64 are removed and insulation layer 62 is isotropically etched to form insulation pattern 66. Insulation pattern 66 is in contact with the protruding portions of device isolation layer 60 and further covers the edges of the active region.

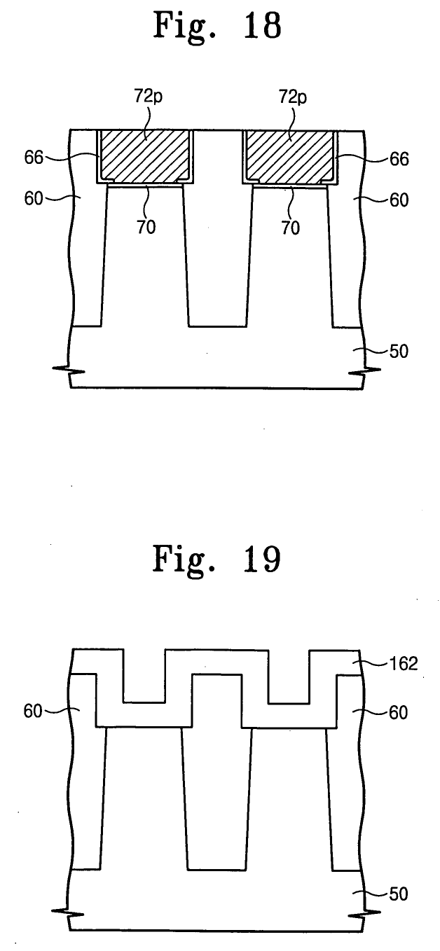

Referring to FIG. 17, a tunnel insulation layer 70 is formed on the active regions between insulation patterns 66. Tunnel insulation layer 70 is preferably formed of a thermal oxide layer. Where tunnel insulation layer 70 is formed of the thermal oxide layer, semiconductor substrate 50 under insulation pattern 66 may be thermally oxidized. However, any thermal oxide layer formed under insulation pattern 66 is generally thinner than the thermal oxide layer formed on the exposed active region between insulation patterns 66.

In general, the sum of the respective thicknesses of the thermal oxide layer and insulation pattern 66 formed at the edges of the active regions is greater than the thickness of tunnel insulation layer 70 formed at central regions of the active regions. However, the thickness of insulation pattern 66 can be adjusted to minimize this difference in thickness.

Referring still to FIG. 17, a floating gate conductive layer 72 is formed on semiconductor substrate over the active regions, tunnel insulation layer 70, insulation patterns 66, and device isolation layer 60. Floating gate conductive layer 72 is formed to completely fill a cavity region between insulation patterns 66.

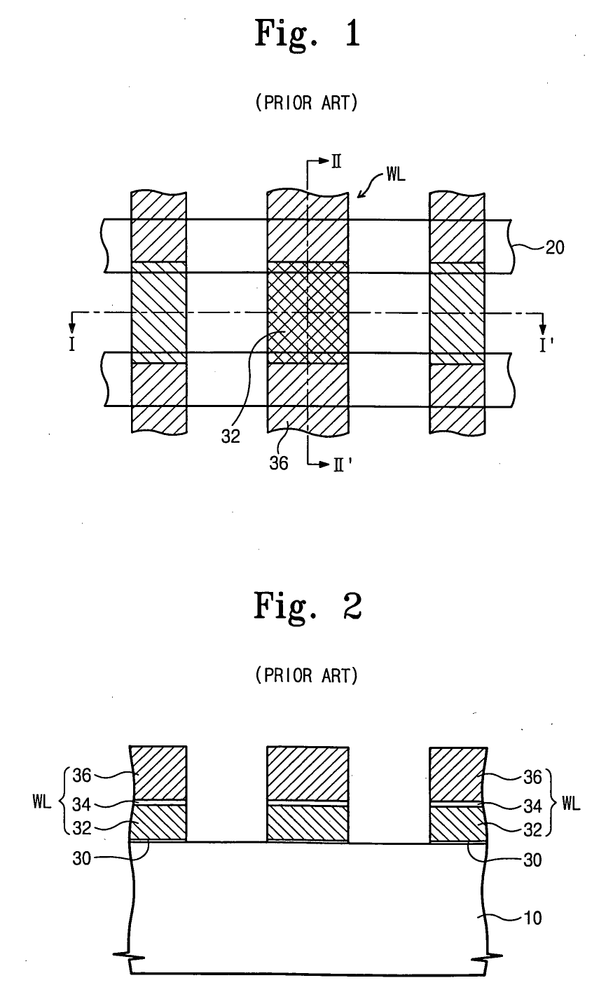

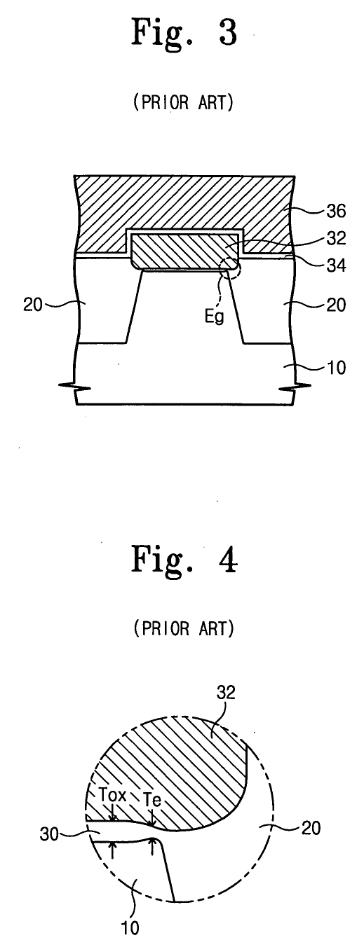

Referring to FIG. 18, floating gate conductive layer 72 is planarized until a top surface of device isolation layer 60 is exposed. As a result, a floating gate pattern 72p is formed on the active regions between device isolation layer 60. Device isolation layer 60 typically defines the active regions in the shape of stripes such as those illustrated in FIG. 1. Accordingly, floating gate pattern 72p also generally has a stripe shape like that of the active regions. In addition, the top surface of floating gate pattern 72p is aligned with the top surface of the protruding portions of device isolation layer 60. Insulation pattern 66 is interposed between device isolation layer 60 and floating gate pattern 72p. Insulation pattern 66 is in contact with an entire surface of a sidewall and a bottom edge of floating gate pattern 72p.

After floating gate pattern 72p is formed, an intergate dielectric and a control gate conductive layer are formed on the device. The control gate conductive layer, the intergate dielectric, and floating gate pattern 72p are sequentially patterned to form a floating gate 72f such as that illustrated in FIGS. 5 through 7. A distance between floating gate pattern 72p and semiconductor substrate 50 is longer at the edges of the active regions than at center portions of the active regions. Because the distance between floating gate 72f and semiconductor substrate 50 is longer at the edges of the active regions than at the center portions of the active region, a relatively weak electric field typically forms around the edges between the active region and floating gate 72f.

As an alternative to forming insulation pattern 66 covering the edges of the active regions by etching a portion of the insulation layer using the spacer pattern, it is possible to form insulation pattern 66 covering the edges of the active region by performing a blank etch-back process on insulation layer 62.

FIG. 19 through 21 are cross-sectional views illustrating a method of manufacturing a non-volatile memory device according to another embodiment of the invention.

Referring to FIG. 19, device isolation layer 60 is formed on semiconductor substrate 50 as illustrated in FIG. 11 or 13, for example. Thereafter, a portion of device isolation layer 60 and buffer oxide layer 52 are isotropically etched until the active regions are exposed. An insulation layer 162 is conformally formed on semiconductor substrate 50 over the exposed active regions. Insulation layer 162 is preferably formed thicker than insulation layer 62 shown in FIGS. 14 and 15.

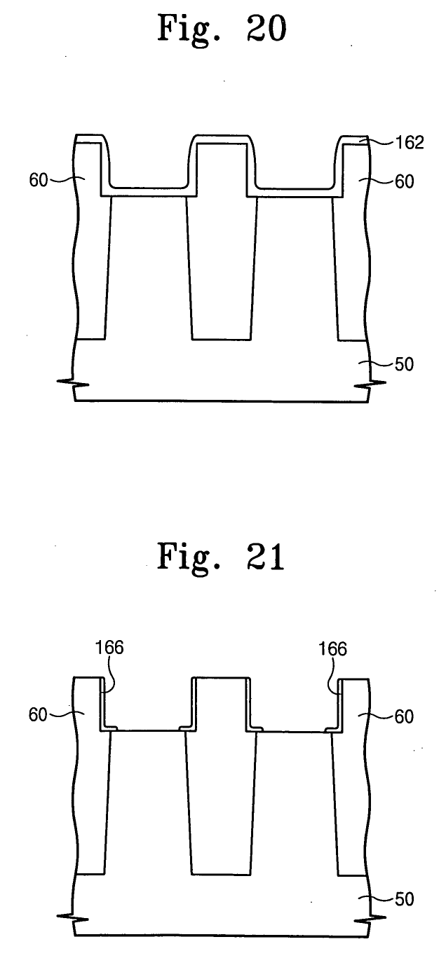

Referring to FIG. 20, insulation layer 162 is anisotropically etched to decrease its thickness. After the anisotropic etching, insulation layer 162 is thicker on sidewalls of device isolation layer 60 than on top surfaces of the active regions and device isolation layer 60. Due to the etching characteristics of insulation layer 162, remaining portions of insulation layer 162 after the anisotropic etching are thicker at upper portions of the sidewalls of device isolation layer 60 than at a lower portions of the sidewalls of device isolation layer 60 near the top surface of the active regions. In addition, edges of remaining insulation layer 162 typically have a rounded shape rather than an angular shape. Insulation layer 162 remaining on the active regions after the anisotropic etching is thicker at edge portions near device isolation layer 60 than at center portions. Accordingly, the top surface of insulation layer 162 generally slopes upward toward device isolation layer 60.

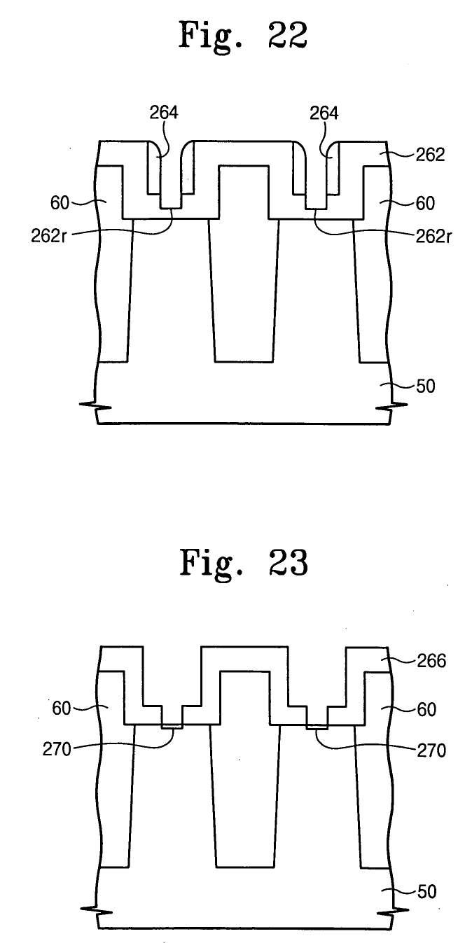

Referring to FIG. 21, insulation layer 162 is isotropically etched so that a center portions of the active regions are exposed, thereby forming an insulation pattern 166 covering the edges of the active regions. Since portions of insulation layer 162 near the edges of the active regions are thicker than portions at the center of the active regions, insulation pattern 166 covers the edges of the active region. However, insulation pattern 166 does not necessarily have the specific shape shown in FIG. 21. The size of the exposed portions of the active regions can be adjusted in consideration of desired rates of tunneling of charges during program/erase operations of the non-volatile memory device.

Subsequently, a process for forming a floating gate pattern such as that described in relation to FIG. 18 is performed. Additional steps can then be performed to complete a non-volatile memory device such as those illustrated in FIGS. 5 through 7.

FIGS. 22 through 26 are cross-sectional views illustrating a non-volatile memory device and associated method of manufacture according to still another embodiment of the invention.

Referring to FIG. 22, an insulation layer 262 is formed in device isolation layer 60. Insulation layer 262 is formed thicker than insulation layer 62 illustrated in FIG. 14. The thickness of insulation layer 262 is preferably large enough so that floating gates formed thereon are thinner than the active regions.

Insulation layer 262 is conformally formed on the active regions and device isolation layer 60. Because of a profile between device isolation layer 60 and semiconductor substrate 50, insulation layer 262 has a plurality of step portions, each having a sidewall over the active regions.

A spacer pattern 264 is formed on the sidewalls of the step portions of insulation layer 262. The sidewalls of the step portions of insulation layer 262 are disposed at positions shifted toward the respective centers of the active regions away from boundaries of the active regions by a predetermined distance. Insulation layer 262 is exposed between spacer patterns 264 formed over the active regions. Exposed insulation layer 262 is etched to a predetermined depth to form recessed regions 262r. Preferably, insulation layer 262 is etched using an anisotropic dry-etching process. In addition, insulation layer 262 is preferably etched so that a predetermined thickness remains on the active regions between spacer patterns 264 in order to protect the active regions from being damaged by the etching process.

Referring to FIG. 23, spacer pattern 264 is removed. When spacer pattern 264 is removed, portions of the active regions become exposed. Thereafter, exposed insulation layer 262 is isotropically etched to form an insulation pattern 266. Preferably, exposed insulation layer 262 is isotropically etched using a wet-etching process so that the exposed active regions are not damaged due to the etching process. Because of the isotropic etching, the exposed portions of the active regions become wider and the sidewalls of the step portions of insulation layer 266 shift toward device isolation layer 60. However, the sidewalls of the step portions of insulation layer 262 are preferably still positioned over the respective active regions. To ensure that the sidewalls of the step portions of insulation layer 262 remain in their respective positions over the active regions after various etching and cleaning processes are performed, insulation layer 262 should be formed with a sufficient thickness to begin with.

Referring still to FIG. 23, a tunnel insulation layer 270 is formed on the exposed active regions. Tunnel insulation layer 270 is preferably formed by performing a thermal oxidation process on semiconductor substrate 50 at the exposed active regions. In the thermal oxidation process, insulation pattern 266 inhibits oxygen diffusion so that semiconductor substrate 50 under insulation pattern 266 is not thermally oxidized. Accordingly, only edges of tunnel insulation layer 270 penetrate beneath insulation pattern 266, and therefore tunnel insulation layer 270 is mostly formed on the active regions between insulation pattern 266.

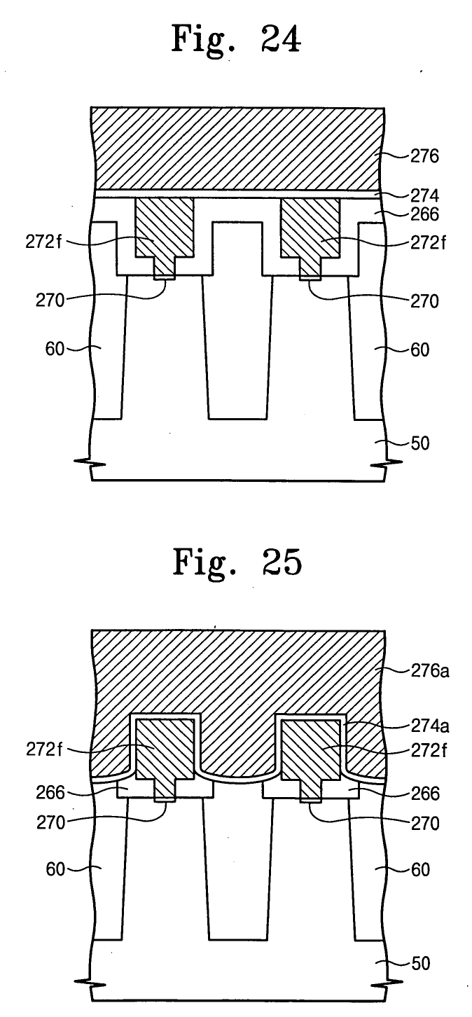

Referring to FIG. 24, processes are performed to form floating gate patterns comprising floating gates 272f, an intergate dielectric 274, and a control gate electrode 276. Floating gates 272f are formed in regions between insulation pattern 266, and are therefore narrower than the respective active regions. In addition, edges of floating gates 272f are formed on insulation pattern 266. Accordingly, a portion of each active region under tunnel insulation layer 270 acts as a channel region of a transistor. As a result, the edges of each active region and the edges of floating gates 272f where electric fields are intensely concentrated are disposed outside the channel of the transistor so that the effect of the electric fields on the operation of the non-volatile memory device is insignificant.

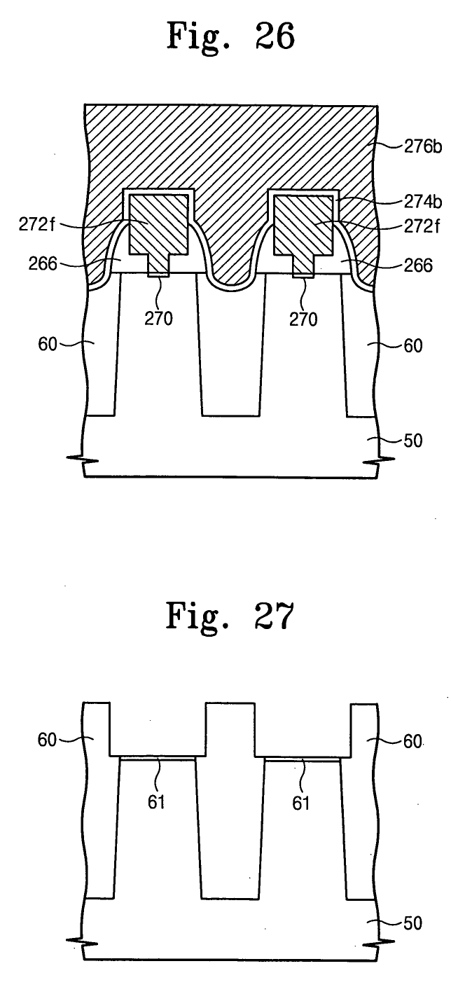

Referring to FIGS. 25 and 26, protruding portions of device isolation layer 60 can be removed before forming intergate dielectric 274. As a result, portions of control gate electrode 276 may extend downward along sidewalls of floating gates 272f as illustrated by the reference label 276a in FIG. 25, or portions of control gate electrode may extend below the top surface of the active regions in a sloping manner as illustrated by the reference label 276b in FIG. 26.

FIGS. 27 through 32 are cross-sectional views illustrating a non-volatile memory device and associated method of manufacture according to still another embodiment of the invention.

Referring to FIG. 27, device isolation layer 60 is isotropically etched so that the distance between protrusions of device isolation layer 60 becomes greater than the widths of corresponding active regions. A heat treatment is performed on device isolation layer 60 and the active regions to form a thermal oxide layer 61 on the active regions.

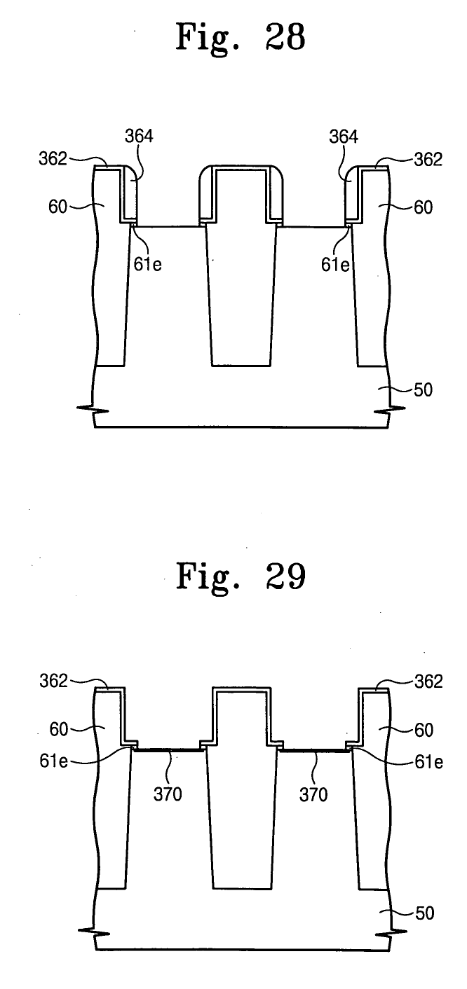

Referring to FIG. 28, an insulation layer 362 is conformally formed over device isolation layer 60 and thermal oxide layer 61. Next, a spacer pattern 364 is formed on sidewall portions of insulation layer 362, and then insulation layer 362 and thermal oxide layer 61 are etched using spacer pattern 364 as an etch mask. After insulation layer 362 and thermal oxide layer 61 are etched, portions of insulation layer 362 remain at edges of the active region over thermal oxide layer 61 and insulation layer 362. Insulation layer 362 is preferably formed of a middle temperature oxide (MTO) layer. Thermal oxide layer 61 has a low interface trap density compared with the MTO layer and it is formed of the same oxide layer as the tunnel insulation layer. Accordingly, thermal oxide layer 61 may act as a buffer oxide layer under the MTO layer.

Referring to 29, spacer pattern 364 is removed and a tunnel insulation layer 370 is formed on the active regions. A thick insulation pattern comprising a thermal oxide pattern 61e and insulation layer 362 stacked in sequence is formed at edges of the active regions. At a center portion of each active region, tunnel insulation layer 370 is formed with a relatively thin thickness.

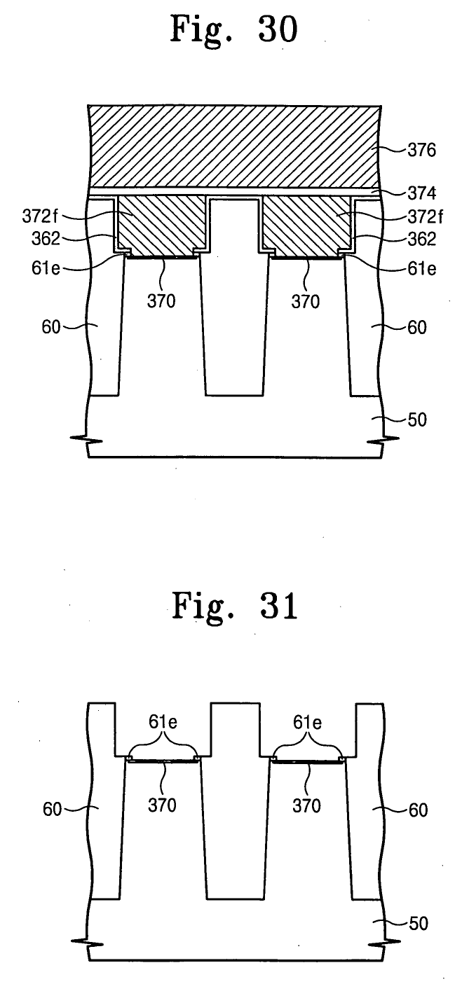

Referring to FIG. 30, various processes are performed to form a floating gate pattern comprising a floating gates 372f, an intergate dielectric 374, and a control gate electrode 376. In the non-volatile memory device illustrated in FIG. 30, an insulation layer between the floating gate 372f and semiconductor substrate 50 is formed thicker at the edges than at center portions of the active regions.

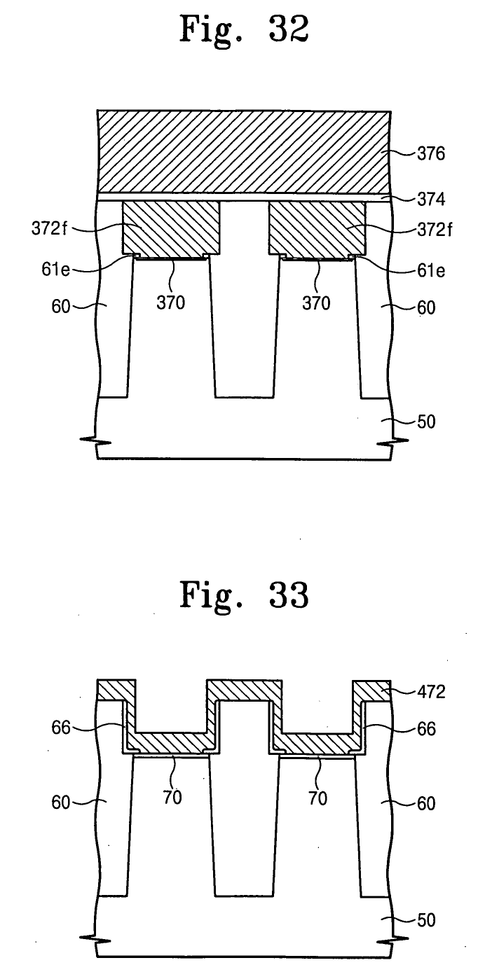

FIG. 31 and FIG. 32 are cross-sectional views illustrating various modifications that can be made to the embodiment of the invention illustrated in FIGS. 27 through 30.

Referring to FIG. 31, insulation layer 362 is removed after removing spacer pattern 364. Preferably, thermal oxide pattern 61e remains after insulation layer 362 is removed. Where insulation layer 362 is formed of the MTO layer using the CVD process, the MTO layer is more rapidly etched rather than the thermal oxide layer so that thermal oxide layer 61e remains. Insulation layer 362 is preferably removed by an isotropic wet etching process.

Next, referring to FIG. 32, various processes are performed to form a floating gate pattern, thus forming a non-volatile memory device in which an insulation layer between floating gates and an underlying substrate is formed thicker at the edges than at center portions of the active regions.

In the exemplary embodiments illustrated above, the floating gates formed on the active regions have flat top surfaces. However, the top surface of the floating gates can have rugged surfaces in order to increase an area in which the floating gate and a corresponding control gate electrode face each other.

FIGS. 33 through 35 are cross-sectional views illustrating an exemplary embodiment of the invention in which a floating gate has a top surface that is not flat.

Referring to FIG. 33, device isolation layer 60, insulation patterns 66, and tunnel insulation layer 70 are formed on semiconductor substrate 50 as described above in relation to FIGS. 8 through 17, for example. Although FIG. 33 illustrates device isolation layer 60, isolation patterns 66, and tunnel insulation layer 70 as formed in the description relating to FIGS. 8 through 17, the embodiment illustrated in FIGS. 33 through 35 can be modified to use various layers and patterns such as those illustrated in FIGS. 19 through 32.

After device isolation layer 60, insulation patterns 60, and tunnel insulation layer 70 are formed on semiconductor substrate 50, a floating gate conductive layer 472 is conformally formed on the resulting structure.

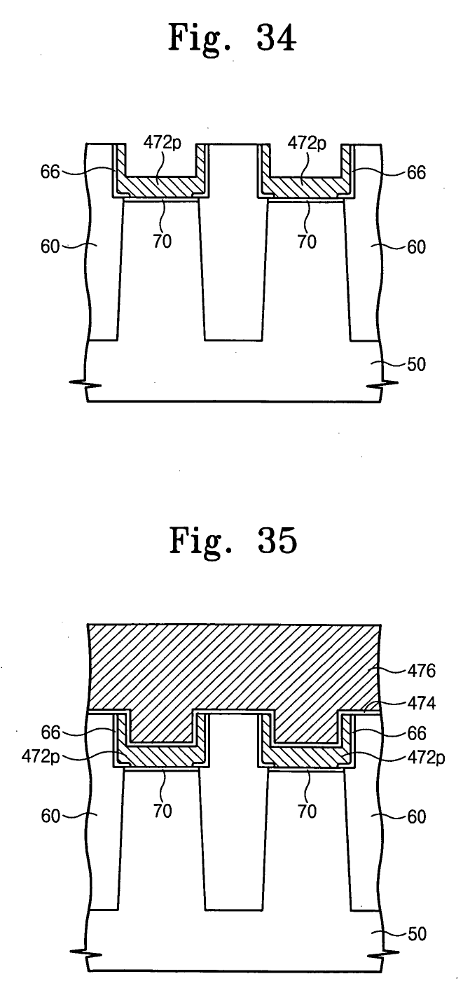

Referring to FIG. 34, floating gate conductive layer 472 is planarized to form floating gate patterns 472p separated from each other on the active regions. Floating gate conductive layer 472 is typically planarized using CMP process. To prevent floating gate conductive layer 472 from being removed from above the active regions during the CMP process, a sacrificial insulation layer is typically formed to fill concave portions of floating gate conductive layer 472. The sacrificial layer is then removed after the CMP process is performed.

Floating gate patterns 472p have U-shaped structures with side portions extending upward along sidewalls of the protruding portions of device isolation layer 60. As a result, floating gate pattern 472p is formed thicker at edges than at central portions, and the top surface of floating gate patterns 472p are not flat.

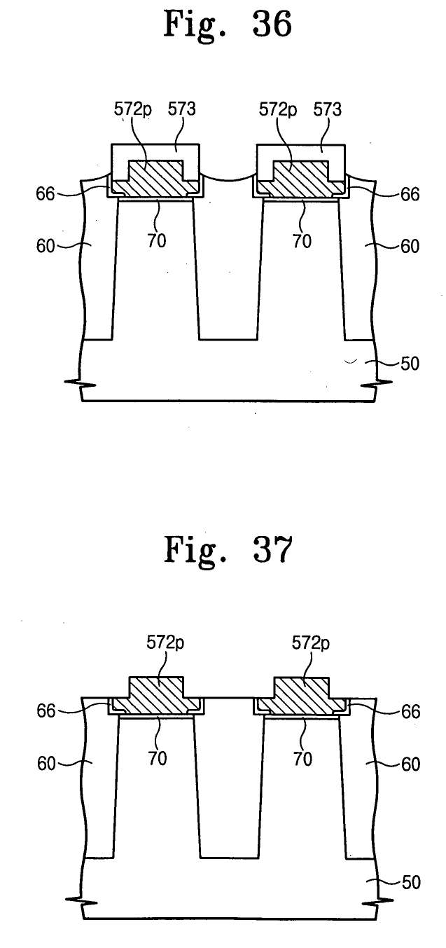

Referring to FIG. 35, an intergate dielectric 474 is conformally formed on the top surface of floating gate patterns 472p, the active regions, and device isolation layer 60. A control gate conductive layer 476 is then formed on intergate dielectric 474. Subsequently, control gate conductive layer 476, intergate dielectric 474 and floating gate patterns 472p are patterned to form a control gate electrode and a floating gate.

In the embodiment illustrated in FIGS. 33 through 35, the protruding portions of device isolation layer 60 may be partially etched after forming floating gate patterns 472p so that portions of the control gate electrode face the sidewalls of floating gate patterns 472p, for example, as in FIGS. 6. Alternatively, device isolation layer 60 may be recessed as in FIG. 7 so that part of it is lower than the top surface of the active region, and thus the portions of the control gate electrode may be extended to a region which is lower than the active region.

FIG. 36 through FIG. 38 are cross-sectional views illustrating another embodiment of the invention in which a floating gate has a top surface that is not flat.

Referring to FIG. 36, device isolation layer 60, insulation patterns 66, and tunnel insulation layer 70 are formed on semiconductor substrate 50 as described above in relation to FIGS. 8 through 17, for example. Although FIG. 36 illustrates device isolation layer 60, isolation patterns 66, and tunnel insulation layer 70 as formed in the description relating to FIGS. 8 through 17, the embodiment illustrated in FIGS. 36 through 38 can be modified to use various layers and patterns such as those illustrated in FIGS. 19 through 32.

Next, floating gate patterns 572p are formed over the active regions. Protruding portions of device isolation layer 60 are then partially removed to expose sidewalls of floating gate patterns 572p. Exposed portions of floating gate patterns 572p are then thermally oxidized. Floating gate patterns 572p are formed of polysilicon, and therefore the exposed portions of floating gate patterns 572p are converted into silicon oxide layers 573. As illustrated in FIG. 36, silicon oxide layers 573 are conformally formed along the exposed portions of corresponding floating gate patterns 572p so that portions of floating gate patterns 572p that are not thermally oxidized remain intact in the form of an upwardly protruding central portion.

Referring to FIG. 37, silicon oxide layers 573 are removed to expose the non-oxidized portions of floating gate patterns 572p. Because part of device isolation layer 60 is covered by silicon oxide layers 573, device isolation layer 60 may be partially removed when silicon oxide layers 573 are removed.

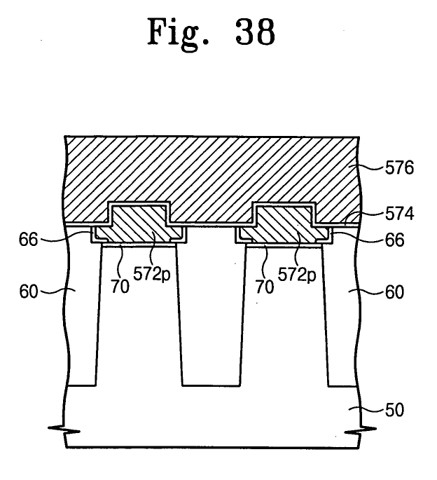

Referring to FIG. 38, an intergate dielectric 574 and a control gate conductive layer 576 are formed on floating gate patterns 572p. Floating gate patterns 572p have a rugged top surface, and therefore an area of control gate conductive layer 576 facing floating gate patterns 572p is enlarged. Subsequently, control gate conductive layer 576, intergate dielectric 574, and floating gate pattern 572p are patterned to form a control gate electrode and a floating gate.

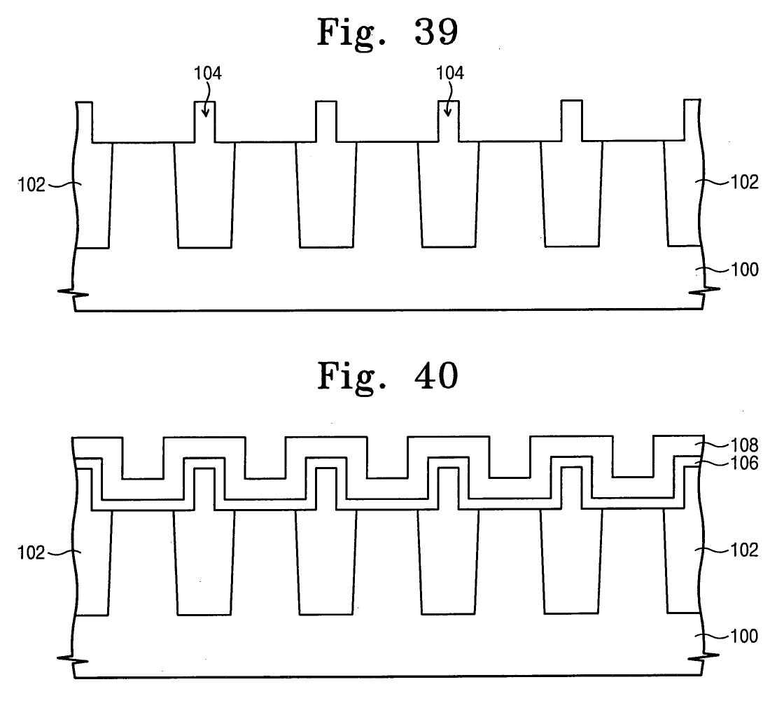

FIGS. 39 through FIG. 45 illustrate a method of manufacturing a non-volatile memory device according to still another embodiment of the present invention.

Referring to FIG. 39, device isolation layers 102 are formed on a semiconductor substrate 100 to define a plurality of active regions. Device isolation layer 102 has protrusions 104 extending above semiconductor substrate 100. Protrusion 104 is typically formed by a conventional trench isolation process or a self-aligned trench isolation process. For example, in one method of forming device isolation layer 102, a hard mask pattern is formed on semiconductor substrate 100. Then, semiconductor substrate 100 is patterned using the hard mask pattern as an etch mask to form a trench in semiconductor substrate 100. An insulation layer is then formed to fill the trench, and the insulation layer is planarized to form device isolation layer 102. Finally, the hard mask layer is removed to expose sidewalls of device isolation layer 102 protruding above semiconductor substrate 100. Each of protrusions 104 has a height equal to a height of the hard mask pattern. Following the removal of the hard mask pattern, sidewalls of protrusions 104 can be isotropically etched to reduce their respective widths. The extent of this reduction can vary, and indeed, in some cases, the isotropic etching step is omitted so that no reduction takes place.

In cases where the reduction in the widths of protrusions 104 causes a distance between adjacent protrusions 104 to become larger than a width of an active region therebetween, an upper portion of a floating gate pattern to be formed later becomes larger than a lower portion of the floating gate formed next to the active region. Accordingly, a coupling ratio of the cell may increase.

Referring to FIG. 40, a first insulation layer 106 is conformally formed over an entire surface of semiconductor substrate 100. In particular, first insulation layer 106 is successively formed device isolation layer 102 including sidewalls of protrusions 104, and on the active regions. First insulation layer 106 typically comprises oxide or nitride. For example, first insulation layer 106 may comprise TCS—SiO₂ or DCS—SiO₂ or SiH₄—SiO₂ according to source gases. Alternatively, first insulation layer 106 may be formed by performing a radical oxidation or nitridation process or a plasma oxidation or nitridation process, or it may be made of O₃ oxide, as examples.

Next, a spacer layer 108 is conformally formed on first insulation layer 106. Spacer layer 108 is made of a material that has an etch selectivity relative to first insulation layer 106 and is typically etched by means of an anisotropic dry etch or an isotropic wet etch process. Further, the material of spacer layer 108 is highly durable against etching solutions and has a high etch selectivity relative to a semiconductor substrate 100 when isotropic wet etch processes are performed. Various materials meeting the above conditions can identified through empirical evaluations and tests. However, as an illustrative example, it will be assumed that spacer layer 108 comprises silicon germanium.

Portions of first insulation layer 106 formed on sidewalls of protrusions 104 preferably have thicknesses such that a region defined by first insulation layer 106 across each active region is wider than the active region. First insulation layer 106 at opposite sides adjacent to each active region form sidewalls above the edges of the active region. Floating gate patterns can be formed in a gap regions between the sidewalls formed by first insulation layer 106 so that floating gate patterns can be formed to be wider than corresponding active regions.

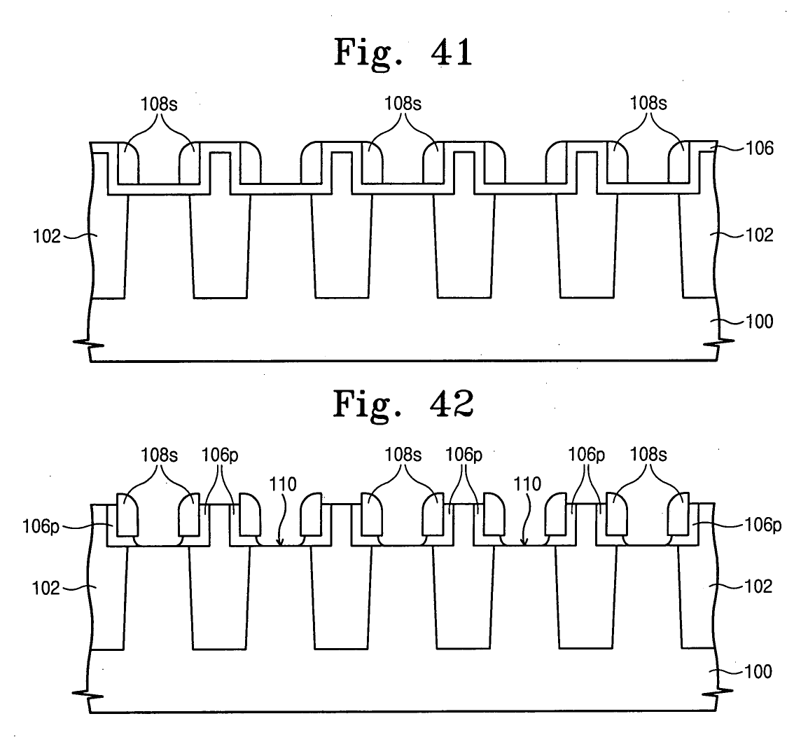

Referring to FIG. 41, spacer layer 108 is anisotropically etched to form spacer patterns 108s on edges of the active regions. Spacer patterns 108s typically overlap device isolation layer 102 and the active regions. However, the location of spacer patterns 108s can be controlled by varying the widths of protrusions 104 and controlling the thickness of first insulation layer 106. Since spacer layer 108 has a high etch selectivity relative to first insulation layer 106, first insulation layer 106 suffers a minimal amount of damage when spacer layer 108 is anisotropically etched.

Referring to FIG. 42, portions of first insulation layer 106 on top of protrusions 104 and the active regions are removed to form edge insulation patterns 106p. The portions of first insulation layer 106 are typically removed using a diluted hydrofluoric acid (HF) solution. First insulation layer 106 is removed from surfaces 110 of the active regions between spacer patterns 108s, thereby increasing the depth of the center of the active regions relative to the edges of the active regions.

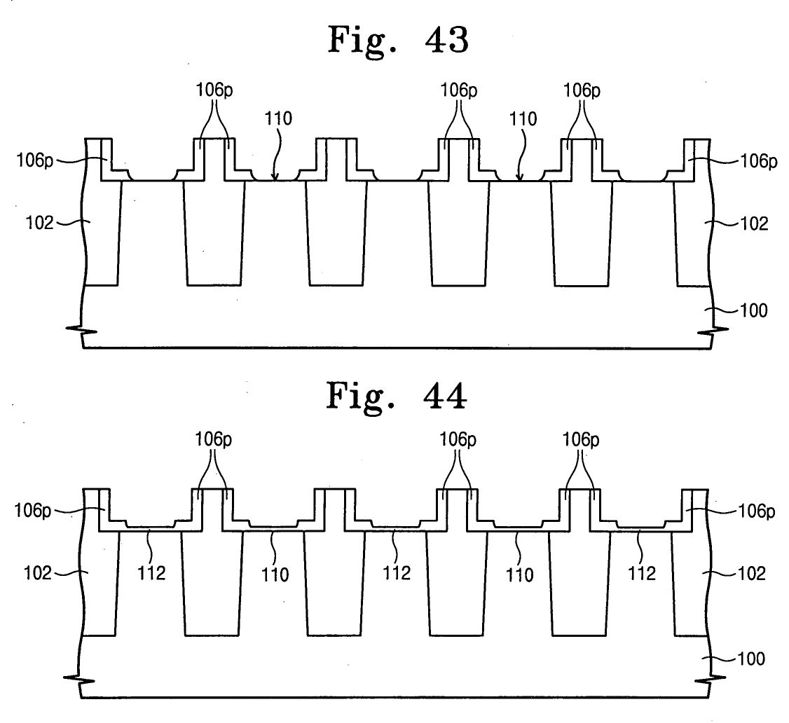

Referring to FIG. 43, spacer patterns 108s are removed to expose edge insulation pattern 106p. Spacer patterns 108s preferably comprise silicon germanium having a significantly higher etch rate than semiconductor substrate 100 under a mixture SC-1 of ammonia, hydrogen peroxide, and deionized water (DI water) so that surfaces 110 of the active regions are not damaged during the removal of spacer patterns 108s.

Referring to FIG. 44, a tunnel insulation layer 112 is formed on surfaces 110 of the active regions. Tunnel insulation layer 112 and edge insulation patterns 106p constitute gate insulators on the active regions. In other words, a thick edge insulation pattern 106p is formed on the edge of each active region, and a tunnel insulation layer 112 is formed at the center of each active region. Tunneling of charges occurs at tunnel insulation layer 112 to practically affect a coupling ratio of the device, which leads to an effect similar to that created by a reduction in an area of a tunnel insulation layer.

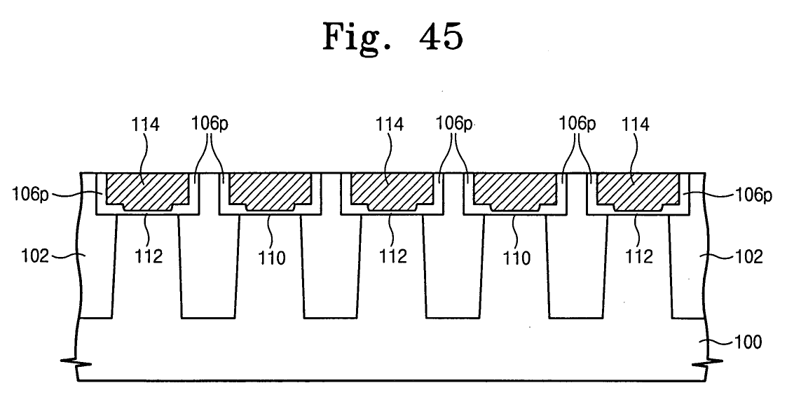

Referring to FIG. 45, a conductive layer is formed over an entire surface of semiconductor substrate 100 to fill regions between edge insulation patterns 106p on the active regions. The conductive layer is planarized to form a floating gate pattern 114 on each of the active regions. A top surface of each floating gate pattern 114 has a larger area than a bottom surface next to a corresponding tunnel insulation layer 112. This is because tunnel insulation layers 112 are locally formed at the centers of the active regions, and the widths of tunnel insulation layers 112 are influenced by the width of protrusions 104 and the thickness of first insulation layer 106.

Although not shown in the figures, protrusions 104 and edge insulation patterns 106p can be partially recessed to partially expose sidewalls of floating gate patterns 114. As a result, floating gate patterns 114 can be widened, and therefore an area of a floating gate formed opposite to a control gate electrode is widened in a subsequent process to increase a coupling ratio of the non-volatile memory device.

In selected embodiments of the invention described above, when a voltage is applied to a control gate electrode of a non-volatile memory device during a write operation or an erase operation, an electric field between edges of an active region and a floating gate of the device is weaker than an electric field between the center of the active region and the floating gate. An insulation layer, which is thicker than a tunnel insulation layer of the device, is interposed between a corner of the active region and a corner of the floating gate to prevent an electric field from concentrating between the corner of the active region and the corner of the floating gate. Thus, an interface trap density of the device is suppressed to enhance the reliability of the device. Further, tunneling of charges occurs at an area that is narrower than an area of the active region, and therefore an area of a tunnel insulation layer contributing to a coupling ratio is reduced to obtain a higher coupling ratio.

The foregoing preferred embodiments are teaching examples. Those of ordinary skill in the art will understand that various changes in form and details may be made to the exemplary embodiments without departing from the scope of the present invention as defined by the following claims.

What is claimed:

1. A non-volatile memory device, comprising:
a device isolation layer defining an active region on a semiconductor substrate;
a tunnel insulation layer disposed on the active region;
an insulation pattern disposed on edges of the active region;
a floating gate disposed on the tunnel insulation layer and the insulation pattern;
a control gate electrode disposed on the floating gate across the active region and the device isolation layer; and,
an intergate dielectric interposed between the floating gate and the control gate electrode;
wherein the insulation pattern is in contact with a bottom edge and a sidewall of the floating gate.

2. The non-volatile memory device of claim 1, wherein the active region is wider than the floating gate.

3. The non-volatile memory device of claim 2, wherein the tunnel insulation layer is disposed on the active region between the insulation pattern.

4. The non-volatile memory device of claim 1, wherein the floating gate is wider than the active region.

5. The non-volatile memory device of claim 4, wherein the tunnel insulation layer is disposed on the active region between the insulation pattern and on edges of the active region below the insulation pattern.

6. The non-volatile memory device of claim 1, further comprising a thermal oxide layer interposed between the insulation pattern and the active region.

7. The non-volatile memory device of claim 1, wherein the floating gate has an edge portion and a center portion, and wherein the edge portion is taller than the center portion.

8. The non-volatile memory device of claim 1, wherein the floating gate has an edge portion and a center portion, and where the edge portion is shorter than the center portion.

9. The non-volatile memory device of claim 1, wherein a top surface of the device isolation layer is aligned with an uppermost surface of the floating gate.

10. The non-volatile memory device of claim 9, wherein the intergate dielectric is interposed between the top surface and the sidewall of the floating gate and the control gate electrode.

11. The non-volatile memory device of claim 10, wherein the insulation pattern is interposed between a portion of the sidewall of the floating gate and the device isolation layer.

12. The non-volatile memory device of claim 1, wherein the device isolation layer has a recessed region extending below a top surface of the active region, and the control gate electrode extends into the recessed region of the device isolation layer.

13. A non-volatile memory device comprising:
a device isolation layer disposed on a semiconductor substrate to define an active region;
insulation patterns disposed on opposite edges of the active region;
a tunnel insulation layer disposed on the active region between the insulation patterns;
a floating gate disposed on the tunnel insulation layer and the insulation patterns, wherein the floating gate is narrower than the active region;
a control gate electrode disposed on the floating gate across the active region and the device isolation layer; and,
an intergate dielectric interposed between the floating gate and the control gate electrode;
wherein the insulation pattern is in contact with a bottom edge and a sidewall of the floating gate.

14. The non-volatile memory device of claim 13, further comprising a thermal oxide layer interposed between the insulation pattern and the active region.

15. The non-volatile memory device of claim 13, wherein the floating gate has an edge portion and a center portion, wherein the edge portion is taller than the center portion.

16. The non-volatile memory device of claim 13, wherein the floating gate has an edge portion and a center portion, wherein the edge portion is shorter than the center portion.

17. The non-volatile memory device of claim 13, wherein a top surface of the device isolation layer is aligned with an uppermost surface of the floating gate.

18. The non-volatile memory device of claim 13, wherein the intergate dielectric is interposed between a top surface and the sidewall of the floating gate, and the control gate electrode.

19. The non-volatile memory device of claim 18, wherein the insulation pattern is interposed between a portion of the sidewall of the floating gate and the device isolation layer.

20. The non-volatile memory device of claim 13, wherein the device isolation layer has a recessed region extending below the top surface of the active region, and the control gate electrode extends into the recessed region of the device isolation layer.

21. A non-volatile memory device comprising:
a device isolation layer disposed on a semiconductor substrate to define an active region;
a tunnel insulation layer disposed on the active region;
insulation patterns disposed on the tunnel insulation layer at opposite edges of the active region;
a floating gate disposed on the tunnel insulation layer and the insulation pattern, wherein the floating gate is wider than the active region;
a control gate electrode disposed on the floating gate across the active region and the device isolation layer; and,
an intergate dielectric interposed between the floating gate and the control gate electrode;
wherein the insulation pattern is in contact with a bottom edge and a sidewall of the floating gate.

22. The non-volatile memory device of claim 21, further comprising a thermal oxide layer interposed between the insulation pattern and the active region.

23. The non-volatile memory device of claim 21, wherein the floating gate has an edge portion and a center portion, wherein the edge portion is taller than the center portion.

24. The non-volatile memory device of claim 21, wherein the floating gate has an edge portion and a center portion, wherein the edge portion is shorter than the center portion.

25. The non-volatile memory device of claim 21, wherein a top surface of the device isolation layer is aligned with an uppermost surface of the floating gate.

26. The non-volatile memory device of claim 21, wherein the intergate dielectric is interposed between a top surface and the sidewall of the floating gate, and the control gate electrode.

27. The non-volatile memory device of claim 26, wherein the insulation pattern is interposed between a portion of the sidewall of the floating gate and the device isolation layer.

28. The non-volatile memory device of claim 21, wherein the device isolation layer has a recessed region extending below the top surface of the active region, and the control gate electrode extends into the recessed region of the device isolation layer.

29. A method of manufacturing a non-volatile memory device, the method comprising:
etching a semiconductor substrate to form a trench defining an active region;
forming a device isolation layer in the trench, the device isolation layer having protruding portions extending above a top surface of the active region;
forming insulation patterns to conformally cover sidewalls of the protruding portions of the device isolation layer and edges of the active region;
forming a tunnel oxide layer on the active region; and,
forming a floating gate pattern on the tunnel oxide layer and the insulation patterns.

30. The method of claim 29, wherein forming the insulation patterns comprises:
conformally forming an insulation layer over the active region and the device isolation layer;
forming a spacer pattern on the insulation layer;
etching the insulation layer using the spacer pattern as an etch mask to recess a portion of the insulation layer;
removing the spacer pattern; and,
etching the insulation layer to expose the active region below the recessed portion of the insulation layer.

31. The method of claim 30, further comprising:
isotropically etching the device isolation layer to make a distance between adjacent protruding portions of the device isolation layer become greater than a width of the active region.

32. The method of claim 31, wherein the insulation layer is thickly formed so that a maximum width of the insulation pattern is smaller than the width of the active region.

33. The method of claim 32, wherein the tunnel insulation layer is formed on the active region between adjacent portions of the insulation pattern.

34. The method of claim 31, wherein the conformal insulation layer is formed with a thickness sufficient to make a maximum width of the insulation pattern greater than the width of the active region.

35. The method of claim 34, wherein the tunnel insulation layer is formed on the active region between the insulation patterns and at the edges of the active region below the insulation patterns.

36. The method of claim 29, wherein forming the insulation patterns comprises:
conformally forming an insulation layer over the active region and the device isolation layer;
anisotropically etching the insulation layer to a predetermined depth; and,
isotropically etching the anisotropically etched insulation layer so that the insulation patterns cover the sidewalls of the protruding portions of the device isolation layer and the edges of the active region.

37. The method of claim 29, further comprising:
forming a thermal oxide layer on the active region before forming the insulation pattern, and etching the thermal oxide layer after forming the insulation pattern so that the thermal oxide layer remains on the edges of the active region below the insulation pattern.

38. The method of claim 37, further comprising:
before forming the floating gate pattern, removing the insulation pattern.

39. The method of claim 29, further comprising:
partially removing the protruding portions of the device isolation layer to partially expose sidewalls of the floating gate pattern.

40. The method of claim 29, further comprising:
partially removing the device isolation layer to form a recessed portion extending below a top surface of the active region.

41. The method of claim 29, wherein forming the floating gate pattern comprises:
forming a conductive layer to fill a space between the protruding portions of the device isolation layer; and,
patterning the conductive layer to expose a top surface of the insulation pattern.

42. The method of claim 41, further comprising:
partially removing the protruding portions of the device isolation layer to partially expose sidewalls of the floating gate pattern;
thermally oxidizing the exposed sidewalls and a top surface of the floating gate pattern; and,
removing a thermally oxidized portion of the floating gate pattern.

43. The method of claim 29, wherein forming the floating gate pattern comprises:
conformally forming a conductive layer on the active layer and the protruding portions the device isolation layer;
forming a sacrificial layer over the active region to fill a concave region of the conductive layer; and,
planarizing the sacrificial layer and the conductive layer to expose a top surface of the insulation pattern.

44. A method of manufacturing a non-volatile memory device, the method comprising:
forming a device isolation layer having protruding portions extending upward from a semiconductor substrate and defining an active region in the semiconductor substrate;
forming a first insulation layer to conformally covering the protruding portions of the device isolation layer and the active region;
forming a spacer pattern comprising silicon germanium on sidewall portions of the first insulation layer formed on the protruding portions of the device isolation layer, the spacer pattern covering edges of the active region;
etching the first insulating layer using the spacer pattern as an etch mask to form an edge insulation pattern covering the edges of the active region;
removing the spacer pattern; and,
forming a tunnel insulation layer on the active region.

45. The method of claim 44, wherein the first insulation layer is wet etched to form the edge insulation pattern.

46. The method of claim 44, wherein the first insulation layer is etched using an etching solution having a higher etch rate with respect to the first insulation layer than the semiconductor substrate.

47. The method of claim 44, wherein the spacer pattern is removed using a wet etching process.

48. The method of claim 47, wherein the spacer pattern is removed using an etching solution having a higher etch rate with respect to the spacer pattern than with respect to the edge insulation pattern, the device isolation layer, and the semiconductor substrate.

49. The method of claim 47, wherein the spacer pattern is removed using a mixture of ammonia, hydrogen peroxide, and deionized water.

50. A method of manufacturing a non-volatile memory device, the method comprising:
forming a device isolation layer having a protruding portions extending upward from a semiconductor substrate and defining an active region in the semiconductor substrate;
etching back sidewalls of the protruding portions to increase a distance between adjacent protruding portions on opposite sides of the active region to more than a width of the active region;
forming a first insulation layer conformally covering the protruding portions and the active region;
forming a spacer pattern comprising silicon germanium on sidewall portions of the first insulation layer formed on the protruding portions of the device isolation layer, the spacer pattern covering edges of the active region;
etching the first insulation layer using the spacer pattern as an etch mask to form an edge insulation pattern covering the edges of the active region;
removing the spacer pattern; and,
forming a tunnel insulation layer on the active region.

51. The method of claim 50, wherein the first insulation layer is formed so that a width of a gap defined by adjacent inner portions of the first insulation layer formed on the protruding portions of the device isolation layer is larger than a width of the active region.

52. The method of claim 50, wherein the spacer pattern overlaps the device isolation layer and a top surface of the active region.

53. The method of claim 50, wherein the first insulation layer is wet etched to form the edge insulation pattern.

54. The method of claim 53, wherein the first insulation layer is etched using an etching solution having a higher etch rate with respect to the first insulation layer than with respect to the semiconductor substrate.

55. The method of claim 50, wherein the spacer pattern is removed by a wet etching process.

56. The method of claim 55, wherein the spacer pattern is removed using an etching solution having a higher etch rate with respect to the spacer pattern than with respect to the edge insulation pattern, the device isolation layer, and the semiconductor substrate.

57. The method of claim 55, wherein the spacer pattern is removed using a mixture of ammonia, hydrogen peroxide, and deionized (DI) water.

58. The method of clam 50, further comprising:
forming a floating gate pattern in a gap region defined by the edge insulation pattern;
wherein the first insulation layer is formed on the active region with a gap wider than the active region, and the floating gate pattern is formed to overlap the active region and a top surface of an edge of the device isolation layer adjacent to the active region.
